(19) United States
(12) Patent Application Publication
(10) Pub. No.: US 2026/0220317 A1
(43) Pub. Date: Jul. 30, 2026

(54) DXF data import model construction method, system and medium

(71) Applicant: XPEEDIC CO., LTD., Shanghai (CN)

(72) Inventors: Wenliang Dai, Shanghai (CN); Liguo JIANG, Shanghai (CN); Ziyou WANG, Shanghai (CN); Yunzhu DU, Shanghai (CN); Bin LUO, Shanghai (CN)

(73) Assignee: XPEEDIC CO., LTD., Shanghai (CN)

(21) Appl. No.: 19/143,500

(22) PCT Filed: Dec. 20, 2023
(86) PCT No.: PCT/CN2023/140176

§ 371 Date: Jun. 26, 2025

(30) Foreign Application Priority Data
Oct. 24, 2023 (CN) 202311391540.2

(51) Int. Cl. G06F 30/12

(52) U.S. Cl. CPC G06F 30/12

(57) ABSTRACT

A DXF data import modeling method, a system, and a medium. The present invention provides a DXF data import modeling method, used for solving the problems that an existing DXF data import operation is complex and the modeling effect cannot be visually displayed. The method comprises: reading DXF data and constructing an entity database; constructing a rendering database; creating layers; constructing a mapping relation table between a layer ID and an entity ID; constructing a layer configuration information table; monitoring configuration information in the layer configuration information table, and synchronously updating rendering data correspondingly; and when the configuration information is completed, ending the import modeling process.

### TECHNICAL FIELD

The present invention relates to the technical field of EDA model simulation, and more specifically, relates to a DXF data import model construction method, system and medium.

### BACKGROUND TECHNOLOGY

Drawing exchange format (DXF) is a drawing interchange format highly compatible for CAD files, supporting a variety of file design types and a variety of CAD software and are widely used in the industry, therefore, simulation for imported DXF data is vital. As DXF data are two-dimensional vector data format, when importing DXF data, different simulation software has different treatments. Some simulation software imports all the DXF data, deletes useless data, stretches and translates useful data. For other software, selection of imported data is done during importing, however, 3D model data are not shown, for example HFSS, which exhibits the DXF data in the form of layer tables, whether to import can be selected, and after importing, all the data types are sheets or lines by default, thereafter, three-dimensional stretching operations are done, and the entire operation process is redundant and not obvious. Overall, for DXF data import model construction currently available, in some cases no importation stage is provided, in other cases, during DXF data importing, it is only possible to select whether to import layers, the established layer tables are not good enough to display 3D rendering effects, and no Elevation and Thickness information configuration is available. After importing the DXF data, all the Entities become individual sheets or lines, layer information is lost and users cannot configure accurately as per the layers.

For example, a Chinese patent application no. CN202210126881.6 published on Mar. 11 2022, discloses a simulation circuit generation method based on switch cabinet construction drawings, comprising: analyzing DXF files, obtaining CAD geometric primitives; establishing a geometric primitive database for the devices, storing mapping relationships between the devices and the geometric primitives; matching all the devices in the geometric primitive database and the CAD geometric primitives and obtaining a final result set; identifying the device set in the final result set, generating a topological relationship result set for the devices; and generating a simulation circuit according to the topological relationship result set. Deficiencies of this patent application are that: although traditionally complex configuration processes are made automatic and graphic and the cost is reduced; accurate modeling is not possible and precision is poor.

### SUMMARY OF INVENTION

### 1. Technical Problems to be Solved

In view of the problem that DXF data importation involves complex operations and model construction effects cannot be displayed visually, the present invention provides a DXF data importation model construction, method and medium. In the present invention, upon changes of configuration, rendering effects are renewed synchronously according to the entity database, the rendering database and the mapping relationship table, so users can know the model construction effects intuitively after importation, loading, model construction and simulation of DXF data can be facilitated; operations can be simplified, what we see is what we get, and operation efficiency can be improved.

### 2. Technical Solution

To address the technical problems, the present invention uses the following technical solution.

A DXF data importation model construction method, comprising:
reading DXF data, building an entity database; wherein each of entity data in the entity database corresponds a unique label, that is, each of rendering data corresponds to a unique Render ID;
creating a plurality of layers, each of the plurality of layers corresponds to a unique mark, that is, each of the plurality of layers has a unique Layer ID;
building a mapping relationship table between the Layer IDs and the Entity IDs;
creating a layer configuration table;
monitoring whether configuration in the layer configuration table has been changed, upon change, renewing the rendering data according to the entity database, the rendering database, and the mapping relationship table; and
upon completion of configuration, importation for model construction is over.

Further, the entity data in the entity database comprises straight line sections, circles, arcs, polylines and polygons.

Further, the entity data of the straight line sections comprise starting points and end points of the straight line sections; the entity data of the circles comprise center points and radiuses of the circles; the entity data of the arcs comprise circle centers, radiuses, initiating angles and end point angles; the entity data of the polylines comprise starting points and end points of the polylines and the entity data of the polygons comprise vertexes of the polygons.

Further, the layer configuration table comprises layer descriptions, layer colors, layer heights, layer thicknesses, layer materials and whether the plurality of layers have been imported.

Further still, upon detection of change of the configuration in the layer configuration table, operations for renewing the rendering data synchronously comprise:
where a layer color is changed, finding the entity data via the mapping relationship table, locating the corresponding rendering data of the entity data via the rendering database, obtaining the rendering data corresponding to the plurality of layers and renewing a color of the rendering data;
where a layer height is changed, finding the entity data via the mapping relationship table, locating original DXF data corresponding to the plurality of layers in the rendering database, translating data to the layer heights and renewing data rendering effects as per the layer color;
where a layer thickness changes, finding the entity data via the mapping relationship table, locating the original DXF data corresponding to the plurality of layers in the entity database, stretching the data in the plurality of layers, translating the data to the layer height, and finally renewing the data rendering effects as per the layer color; and
where the layer material changes, renewing the layer configuration table, renewing of data rendering is not required.

Further, upon completion of data configuration, data for which importation is not required in the layer configuration table are deleted, wherein deletion comprises deleting data model construction data; and deleting the data from rendered 3D scenes.

A system for using the DXF data import model construction method as set forth in the foregoing paragraphs, comprising:
an entity database construction module: configured to read DXF data, building an entity database; wherein each of the entity data in the entity database corresponds to a unique label, that is, each of the entity data corresponds to a unique entity ID;
a rendering database construction module: configured to render the entity data, building the rendering database; wherein the rendering data corresponding to each of the entity data have a unique mark, that is, each of the rendering data corresponds to a unique render ID;
a layer creation module: configured to create the plurality of layers, and each of the plurality of layers corresponds to a unique label;
a mapping relationship table building module: configured to build a mapping relationship table between the layer IDs and the entity IDs;
a layer configuration table construction module: configured to build the layer configuration table;
a rendering data synchronous renewal module: configured to monitor whether configuration in the layer configuration table has been changed, and renew the rendering data upon change according to the entity database, the rendering database and the mapping relationship table; and
a display module: configured to display after information configuration.

A non-transitory computer readable medium stored with a computer program, wherein the computer program when being executed by a processor will have the processor execute the DXF data importation model construction method set forth in the foregoing paragraphs.

### 3. Beneficial Effects

Compared with the prior art, the beneficial effects of the present invention are:
(1) In the present invention, by constructing the entity database, the rendering data and the mapping relationship table between the layer IDs and the entity IDs, 3D display of two-dimensional vector DXF data as per layers is realized, in the meanwhile, corresponding layer configuration tables are configured as per the layers, upon changes of the configuration, the rendering effects can be renewed synchronously according to the entity database, the rendering database and the mapping relationship table, so that the user can view the model construction effects after importation visually; loading, model construction and simulation of DXF data is greatly facilitated; operations are simplified, what we see is what we get, batched processing is supported, import and export of configuration is made available and user operation efficiency is improved;
(2) In the present invention, a variety of data comprising straight line sections, circles, arcs, polylines and polygons are included when building the entity database, and the full-reaching entity database is built; in the meanwhile, for different types of data, records of the entity data are different, data construction accuracy for different types of data is promised so as to improve building accuracy of the entire entity database and subsequently, during rendering, entity data in the entity database can be found precisely and quickly; and
(3) In the present invention, the modules in the system are simple, by configuring the corresponding database during DXF data importation, 3D display effects can be shown synchronously, 2D models are translated and stretched to be 3D data; the problem of the low efficiency due to the model construction effects required for multiple operations previously can be avoided, and user experience is significantly improved.

### BRIEF DESCRIPTION OF DRAWINGS

FIG. 1 is an overall process schematic diagram showing a method according to the present invention; and

FIG. 2 is a flow chart diagram showing synchronous renewal of rendering data.

### EMBODIMENTS

Hereinafter a further description of the present invention will be given in conjunction with the embodiments and the drawings.

### Embodiment 1

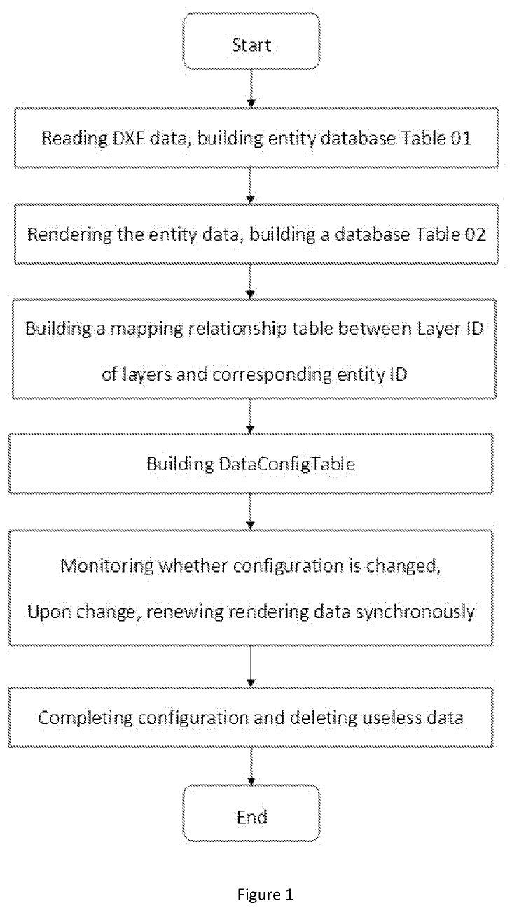

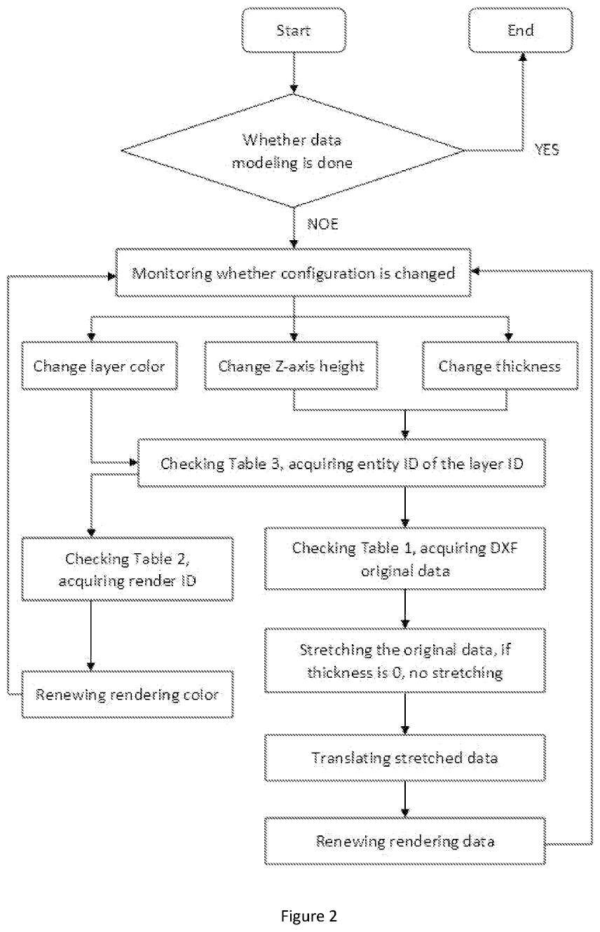

With reference to FIGS. 1 and 2, FIG. 1 is an overall flow chart diagram showing the method provided in the present invention; FIG. 2 is a flow chart diagram showing synchronous renewal of rendering data.

Specifically, in the present embodiment, as shown in FIGS. 1-2, a DXF data importation model construction method, comprising:
S1: reading DXF data, building an entity database (Table 01); wherein each of the entity data in the entity database has a unique label, that is, each of the entity data corresponds to a unique entity ID; in the entity database, one-one mapping between each of the entity data and the entity ID corresponding to each of the entity data, and knowing the entity ID the entity data is become available and knowing the entity data the entity ID can be obtained;
Specifically, in the present step, the entity data in the entity database comprise straight line sections, circles, arcs, polylines and polygons so as to promise that the entity database is constructed with a full reach; for those different entity data, what is recorded in each type of entity data is different too, specifically: the entity data of the straight line sections comprise starting points and ending points of the straight line sections; the entity data of the circles comprise center points and radiuses of the circles; the entity data of the arcs comprise centers, radiuses, starting angles and ending angles of the arcs; the entity data of the polylines comprise starting points and ending points of the line sections; the entity data of the polygons comprise all vertexes of the polygons. For different types of data different data recording methods are used, uniqueness and accuracy of each of the data records can be promised and accuracy of the entire entity database can be promised, so that in the subsequent rendering operation, corresponding entity data can be accurately and quickly found in the entity database.
S2: rendering the entity data, building a rendering database (Table 2); wherein the rendering data corresponding to each of the entity data have a unique mark, that is, each of the rendering data corresponds to a unique render ID; in the rendering database, each of the entity data corresponds to one of the rendering data, each of the rendering data corresponds to a unique render ID; that is, each of the entity data corresponds to a render ID, one-one mapping exists therebetween, and knowing the entity data the render IDs can be know and knowing the render IDs the entity data can be known too;
S3: creating layers, each of the layers corresponds to a unique mark, that is, each of the layers corresponds to a unique layer ID; subsequently a mapping relationship table (Table 03) is built between the layer IDs and the entity IDs;

In the present step, each of the layer will correspond to a set of entity IDs, so that subsequently, the same set of entity IDs can be set jointly.
S4: building a layer configuration table (DataConfigTable); specifically, the layer configuration table comprises layer descriptions, layer colors, layer heights, layer thicknesses, layer materials and whether to import the layers;
S5: monitoring whether configuration in the layer configuration table is changed, upon change, renewing synchronously the rendering data according to the entity database, the rendering database and the mapping relationship table; specifically, upon monitoring of changes of configuration in the layer configuration table, operations for renewing the rendering data synchronously comprises specifically:
Where the layer colors change, finding the entity data in the mapping relationship table, finding the rendering data corresponding to the entity data in the rendering database and obtaining the rendering data corresponding to the layers, and renewing the colors of the rendering data;
Where the layer heights (Z-axis height) changes, finding the entity data in the mapping relationship table, finding corresponding original DXF data corresponding to the layer, translating the data to the layer height, and renewing data rendering effects as per the layer colors;
Where the layer thicknesses change, finding the entity data in the mapping relationship table, finding corresponding original DXF data in the entity database, stretching the layer data and translating the data to the layer height, finally renewing the data rendering effects as per the layer colors;
Where the layer materials change, directly renewing the layer configuration table without renewing data rendering.
S6: after configuration, an entire importation and modeling process is concluded; in the present step, after configuration, the step further comprises deleting data for which importation is not required from the layer configuration table, and deletion comprises deleting data modeling data and deleting the data from rendered 3D scenes.

In the present invention, by constructing the entity database, the rendering data and the mapping relationship table between the layer IDs and the entity IDs, 3D display of two-dimensional vector DXF data as per layers is realized, in the meanwhile, corresponding layer configuration tables are configured as per the layers, upon changes of the configuration, the rendering effects can be renewed synchronously according to the entity database, the rendering database and the mapping relationship table, so that the user can view the model construction effects after importation visually; loading, model construction and simulation of DXF data is greatly facilitated; operations are simplified, what we see is what we get, batched processing is supported, import and export of configuration is made available and user operation efficiency is improved.

### Embodiment 2

A system for using the DXF data import model construction method as set forth in the foregoing paragraphs, comprising:
An entity database construction module: configured to read DXF data, building an entity database; wherein each of the entity data in the entity database corresponds to a unique label, that is, each of the entity data corresponds to a unique Entity ID;
A rendering database construction module: configured to render the entity data, building the rendering database; wherein the rendering data corresponding to each of the entity data have a unique mark, that is, each of the rendering data corresponds to a unique Render ID;
A layer creation module: configured to create layers, and each of the layers corresponds to a unique label;
A mapping relationship table building module: configured to build a mapping relationship table between the layer IDs and the entity IDs;
A layer configuration table construction module: configured to build the layer configuration table;
A rendering data synchronous renewal module: configured to monitor whether configuration in the layer configuration table has been changed, and renew the rendering data upon change according to the entity database, the rendering database and the mapping relationship table; and
A display module: configured to display after information configuration.

In the present invention, the modules in the system are simple, by configuring the corresponding database during DXF data importation, 3D display effects can be shown synchronously, 2D models are translated and stretched to be 3D data; the problem of the low efficiency due to the model construction effects required for multiple operations previously can be avoided, and user experience is significantly improved.

### Embodiment 3

A non-transitory computer readable medium stored with a computer program, wherein the computer program when being executed by a processor will have the processor execute the DXF data importation model construction method set forth in the foregoing paragraphs. It shall be noted that, for those skilled in the art, besides implementing the system and modules provided in the present invention in the form of computer readable program codes, the steps of the foregoing method can be programmed logically to have the system and the modules provided in the present invention being executed in the form of logical gates, switches, special integrated circuits, programmable logical controllers and embedded microcontrollers. Therefore the system and the modules in the present invention can be deemed as hardware parts, and the modules for implementing the programs included therein can be regarded as internal structures of the hardware parts, also the modules for implementing the variety of functions can be regarded as software programs for realizing the method or structures in the hardware parts.

The foregoing embodiments are only a description of some preferred embodiments of the present invention, without limiting the idea and the scope of the present invention, without departing from the essence of the present invention, those skilled in the art can make a variety of modifications and improvements to the technical solutions of the present invention, which shall fall into the protection scope of the present invention.

1. A drawing exchange format (DXF) data importation model construction method, comprising:
reading DXF data, building an entity database; wherein each of entity data in the entity database corresponds a unique label, that is, each of rendering data corresponds to a unique Render ID;
creating a plurality of layers, each of the plurality of layers corresponds to a unique mark, that is, each of the plurality of layers has a unique Layer ID;
building a mapping relationship table between the Layer IDs and the Entity IDs;
creating a layer configuration table;
monitoring whether configuration in the layer configuration table has been changed, upon change, renewing the rendering data according to the entity database, the rendering database, and the mapping relationship table; and
upon completion of configuration, importation for model construction is over.

2. The DXF data importation model construction method according to claim 1, wherein the entity data in the entity database comprises straight line sections, circles, arcs, polylines and polygons.

3. The DXF data importation model construction method according to claim 2, wherein the entity data of the straight line sections comprise starting points and end points of the straight line sections; the entity data of the circles comprise center points and radiuses of the circles; the entity data of the arcs comprise circle centers, radiuses, initiating angles and end point angles; the entity data of the polylines comprise starting points and end points of the polylines and the entity data of the polygons comprise vertexes of the polygons.

4. The DXF data importation model construction method according to claim 1, wherein the layer configuration table comprises layer descriptions, layer colors, layer heights, layer thicknesses, layer materials and whether the plurality of layers have been imported.

5. The DXF data importation model construction method according to claim 1, wherein upon detection of change of the configuration in the layer configuration table, operations for renewing the rendering data synchronously comprise:
where a layer color is changed, finding the entity data via the mapping relationship table, locating the corresponding rendering data of the entity data via the rendering database, obtaining the rendering data corresponding to the plurality of layers and renewing a color of the rendering data;
where a layer height is changed, finding the entity data via the mapping relationship table, locating original DXF data corresponding to the plurality of layers in the rendering database, translating data to the layer heights and renewing data rendering effects as per the layer color;
where a layer thickness changes, finding the entity data via the mapping relationship table, locating the original DXF data corresponding to the plurality of layers in the entity database, stretching the data in the plurality of layers, translating the data to the layer height, and finally renewing the data rendering effects as per the layer color; and
where the layer material changes, renewing the layer configuration table, renewing of data rendering is not required.

6. The DXF data importation model construction method according to claim 1, wherein upon completion of data configuration, data for which importation is not required in the layer configuration table are deleted, wherein deletion comprises deleting data model construction data; and deleting the data from rendered 3D scenes.

7. A system for using the DXF data import model construction method as set forth in claim 1, comprising:
an entity database construction module: configured to read DXF data, building an entity database; wherein each of the entity data in the entity database corresponds to a unique label, that is, each of the entity data corresponds to a unique entity ID;
a rendering database construction module: configured to render the entity data, building the rendering database; wherein the rendering data corresponding to each of the entity data have a unique mark, that is, each of the rendering data corresponds to a unique render ID;
a layer creation module: configured to create the plurality of layers, and each of the plurality of layers corresponds to a unique label;
a mapping relationship table building module: configured to build a mapping relationship table between the layer IDs and the entity IDs;
a layer configuration table construction module: configured to build the layer configuration table;
a rendering data synchronous renewal module: configured to monitor whether configuration in the layer configuration table has been changed, and renew the rendering data upon change according to the entity database, the rendering database and the mapping relationship table; and
a display module: configured to display after information configuration.

8. A non-transitory computer readable medium stored with a computer program, wherein the computer program when being executed by a processor will have the processor execute the DXF data importation model construction method set forth in claim 1.
